(19) United States
(12) Patent Application Publication
(10) Pub. No.: US 2024/0326493 A1
(43) Pub. Date: Oct. 3, 2024

(54) ELECTRONIC APPARATUS AND CABLE PROTECTING UNIT

(71) Applicant: SEIKO EPSON CORPORATION, Tokyo (JP)

(72) Inventors: Yusuke HIGUCHI, MATSUMOTO-SHI (JP); Yohei SAKAI, MATSUMOTO-SHI (JP)

(21) Appl. No.: 18/614,853

(22) Filed: Mar. 25, 2024

(30) Foreign Application Priority Data
Mar. 27, 2023 (JP) 2023-049542

(51) Int. Cl. B41J 29/13; B41J 2/14; B41J 29/54; H01B 7/00; H04N 1/00

(52) U.S. Cl. CPC B41J 29/13; B41J 2/14072; B41J 29/54; H01B 7/0045; H04N 1/00519

(57) ABSTRACT

An electronic apparatus includes: an apparatus body; a door configured to be displaced to an opened state in which the door is opened relative to the apparatus body and a closed state in which the door is closed relative to the apparatus body; a cable provided between the apparatus body and the door; and a cable protecting unit configured to protect the cable. The cable protecting unit includes: a base-portion member; and a movable member provided slidably relative to the base-portion member. When the door is displaced from the closed state to the opened state, the movable member slides relative to the base-portion member to increase a length by which the movable member extends from the base-portion member.

The present application is based on, and claims priority from JP Application Serial Number 2023-049542, filed on Mar. 27, 2023, the disclosure of which is hereby incorporated by reference herein in its entirety.

### BACKGROUND

### 1. Technical Field

The present disclosure includes an electronic apparatus and a cable protecting unit.

### 2. Related Art

JP-A-2001-057611 discloses an image forming apparatus. The image forming apparatus includes an apparatus body including an original-document table and configured to read an original document set on the original-document table to perform printing, and also includes an original-document feeding device attached at the apparatus body and configured to feed the original document onto the original-document table. The image forming apparatus serves as an example of an electronic apparatus. In addition, it discloses that a cable laid over between the apparatus body and the original-document feeding device is inserted into a cable protecting tube. The cable protecting tube is configured to protect the cable in a manner such that the cable is not viewed from the outside. The cable protecting tube serves as an example of a cable protecting unit. In addition, the cable protecting tube is fixed at either the apparatus body or the original-document feeding device, and is provided slidably relative to the other one.

However, with the image forming apparatus disclosed in JP-A-2001-057611, a space used to insert the cable protecting tube needs to be provided at either the apparatus body or the original-document feeding device, which may increase the size of the apparatus.

### SUMMARY

An electronic apparatus includes an apparatus body, an opening-closing member provided displaceably to an opened state in which the opening-closing member is opened relative to the apparatus body and a closed state in which the opening-closing member is closed relative to the apparatus body, a cable provided between the apparatus body and the opening-closing member, and a cable protecting unit configured to protect the cable, in which the cable protecting unit includes a base-portion member, and a movable member provided slidably relative to the base-portion member, and when the opening-closing member is displaced from the closed state to the opened state, the movable member slides relative to the base-portion member to increase a length by which the movable member extends from the base-portion member.

A cable protecting unit provides a cable protecting unit configured to protect a cable provided between an apparatus body and an opening-closing member configured to be displaced to an opened state in which the opening-closing member is opened relative to the apparatus body and a closed state in which the opening-closing member is closed relative to the apparatus body, the cable protecting unit including a base-portion member, and a movable member provided slidably relative to the base-portion member, in which when the opening-closing member is displaced from the closed state to the opened state, the movable member slides relative to the base-portion member to increase a length by which the movable member extends from the base-portion member.

### BRIEF DESCRIPTION OF THE DRAWINGS

FIG. 1 is a perspective view illustrating an electronic apparatus serving as an embodiment of the present disclosure.

FIG. 2 is a schematic side diagram illustrating the configuration of the electronic apparatus.

FIG. 3 is a partial perspective view illustrating the electronic apparatus in which a door is in an opened state.

FIG. 4 is a perspective view illustrating the configuration of a cable protecting unit.

FIG. 5 is a perspective view illustrating the configuration of the cable protecting unit.

FIG. 6 is a perspective view illustrating the configuration of the cable protecting unit.

FIG. 7 is a perspective view illustrating the configuration of the cable protecting unit.

FIG. 8 is a perspective view illustrating the configuration of the cable protecting unit.

FIG. 9 is a perspective view illustrating the configuration of the cable protecting unit.

FIG. 10 is a partial perspective view illustrating the cable protecting unit and its surroundings of the electronic apparatus in a state in which the door is in an opened state.

FIG. 11 is a partial perspective view illustrating the cable protecting unit and its surroundings of the electronic apparatus in a state in which the door is in an opened state.

FIG. 12 is a partial perspective view illustrating a state without the cable protecting unit of the electronic apparatus in a state in which the door is in an opened state.

FIG. 13 is a partial perspective view illustrating the cable protecting unit and its surroundings of the electronic apparatus in a state in which the door is in an opened state.

FIG. 14 is a partial cross-sectional view illustrating the cable protecting unit and its surroundings of the electronic apparatus in a state in which the door is in a closed state.

FIG. 15 is a partial cross-sectional view illustrating the cable protecting unit and its surroundings of the electronic apparatus in a state in which the door is in an opened state.

FIG. 16 is a perspective view illustrating another embodiment of the cable protecting unit.

### DESCRIPTION OF EMBODIMENTS

Below, the present disclosure will be described based on embodiments. An electronic apparatus 10 is, for example, an ink jet-type printer configured to discharge ink serving as an example of a liquid onto a medium M such as a sheet to perform recording. The ink jet-type printer serves as an example of a recording device that performs recording on the medium M. In addition, the electronic apparatus 10 is, for example, a multifunction device. The electronic apparatus 10 has a plurality of functions including a scanning function, a copying function, and a printing function. Note that the electronic apparatus 10 may have a function of facsimile.

In each of the drawings, the same reference signs denote the same members, and redundant description will be omitted. Note that, in the present description, the terms “same”, “identical”, and “simultaneously” do not only mean complete sameness. The terms “same”, “identical”, and “simultaneously” include a case of being the same after consideration, a case of being the same in consideration of manufacturing variations of members, and a case of being the same within a range that does not impair functions. Thus, for example, “both dimensions are the same” means that a dimensional difference between the two dimensions is within ±10% of either of the dimensions, may be within ±5%, and may be within ±3% in consideration of measurement errors and manufacturing variations of members.

In each of the drawings, it is assumed that the electronic apparatus 10 is disposed at a horizontal installation surface. Of the Z-axis perpendicular to the installation surface of the recording device 10, a side of the recording device 10 with respect to the installation surface is referred to as a +Z direction side, and the opposite side is referred to as a −Z direction side. In addition, two axes orthogonal to the Z-axis are each referred to as an X-axis and a Y-axis. Furthermore, directions parallel to the X-axis, the Y-axis, and the Z-axis are referred to as an X-axis direction, a Y-axis direction, and a Z-axis direction, respectively. The X-axis direction includes a +X direction and a −X direction. The Y-axis direction includes a +Y direction and a −Y direction. The Z-axis direction includes a +Z direction and a −Z direction.

The X-axis direction is a depth direction when the electronic apparatus 10 is viewed from the front surface thereof. In addition, the X-axis direction is a width direction of the medium M. Furthermore, the X-axis extends a width direction of a recording unit 20 that will be described later. In addition, the front surface of the electronic apparatus 10 is a surface at a side where an operation unit 14 is located. The operation unit 14 is operated by a user to give an instruction to the electronic apparatus 10.

### 1. First Embodiment

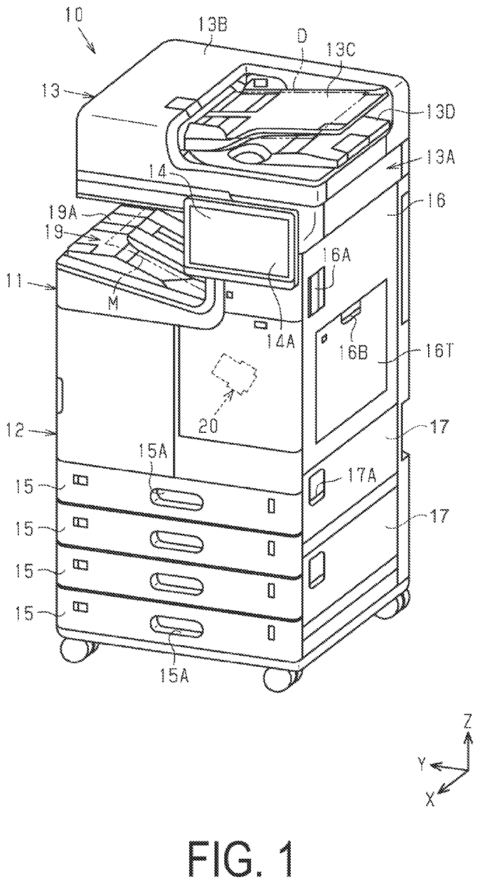

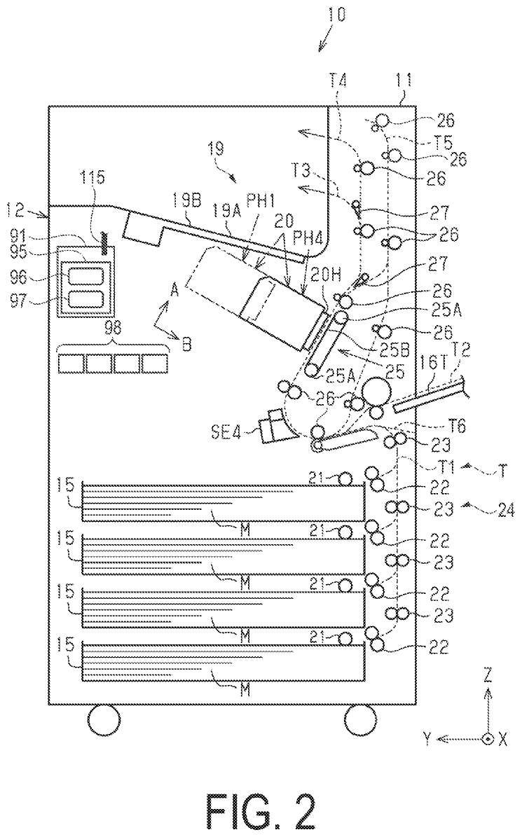

As illustrated in FIG. 1, the electronic apparatus 10 is, for example, a multifunction device. The electronic apparatus 10 includes an apparatus body 11 having a cuboid shape. The electronic apparatus 10 includes a printing unit 12 comprised of the apparatus body 11, and an image reading unit 13 disposed above the printing unit 12. The apparatus body 11 includes a transport path T (see FIG. 2) configured to transport the medium M.

The image reading unit 13 is configured to read an image on an original document D. The image reading unit 13 includes a reading unit 13A configured to read the original document D, and an auto document feeding unit 13B disposed at the upper side of the reading unit 13A. The auto document feeding unit 13B is configured to feed the original document D placed on an original document tray 13C to the reading unit 13A. The reading unit 13A reads the original document D, and discharges, to a discharge tray 13D, the original document D to which reading has been performed. In addition, the reading unit 13A has a flat-head type reading function configured to read the original document D set on an original-document table exposed when the auto document feeding unit 13B, which also functions as an original-document table cover, is opened.

The electronic apparatus 10 includes the operation unit 14 at the apparatus body 11. The operation unit 14 includes a display unit 14A comprised of a touch panel. A user performs a touching operation to the display unit 14A, thereby being able to give an instruction to the electronic apparatus 10. Note that the operation unit 14 may include an operation button.

The electronic apparatus 10 includes a cassette 15 that can accommodate a plurality of media M. The cassette 15 includes one stage or a plurality of stages, and for example, includes four stages. The cassettes 15 are inserted and attached at a lower portion of the apparatus body 11 in a state of being detachable by sliding in the X-axis direction. The plurality of cassette 15 accommodate, for example, different sizes of or different types of media M. The cassette 15 includes a handle 15A that allows a user to hook a finger around at the time of performing a pulling-out operation.

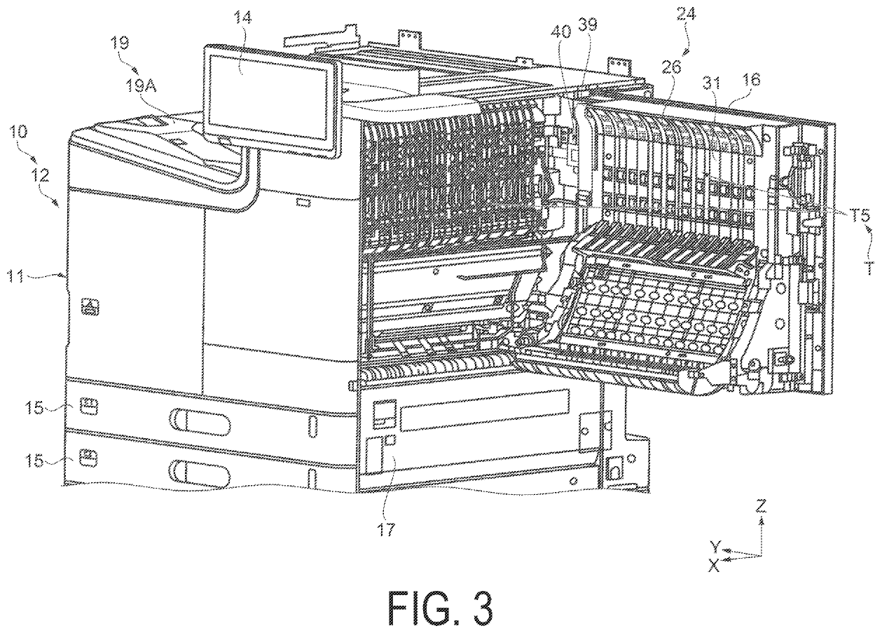

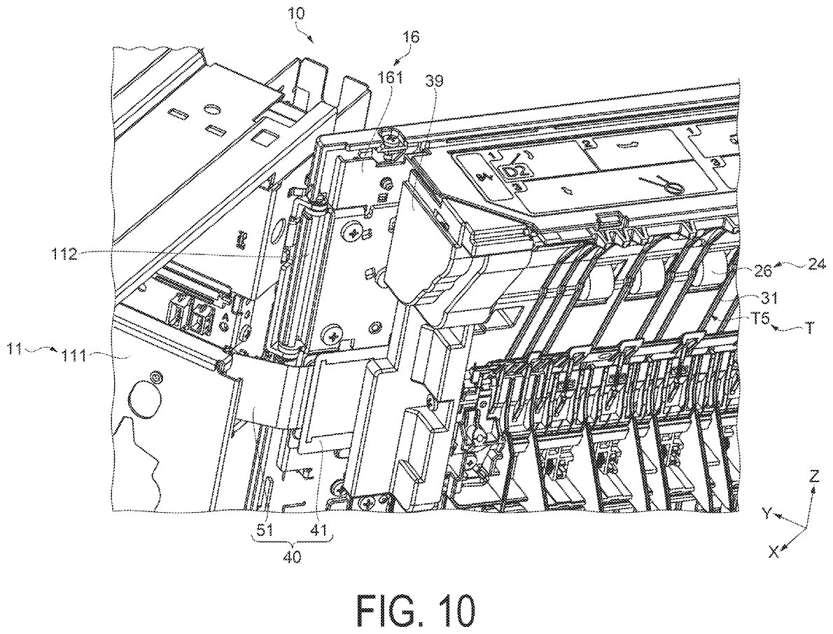

At a side surface of the apparatus body 11 at the −Y direction side, the electronic apparatus 10 includes a door 16 and a lid 17. The door 16 is able to be opened and closed between an opened state (see FIG. 3) in which a transport path T (see FIG. 2) is exposed to the outside and a closed state (see FIG. 1) in which the transport path T is closed. The door 16 is attached to the apparatus body 11 so as to be able to rotate between the opened state and the closed state. The door 16 rotates with the shaft center of the rotational movement shaft 112 (see FIG. 10) along the Z-axis being the center of rotation. The door 16 serves as an example of an opening-closing member provided displaceably to the opened state in which the opening-closing member is opened relative to the apparatus body 11 and the closed state in which the opening-closing member is closed relative to the apparatus body 11.

The door 16 and the lid 17 include handles 16A and 17A used by a user to perform an open-close operation. The door 16 includes a sheet feeding tray 16T that allows a medium M to be mounted. The sheet feeding tray 16T is provided so as to be able to be opened and closed relative to the door 16. The sheet feeding tray 16T includes a handle 16B used by a user to perform an open-close operation.

As illustrated in FIGS. 1 and 2, the electronic apparatus 10 includes, at the apparatus body 11, the recording unit 20 configured to perform recording on the medium M. The recording unit 20 performs recording, for example, on the medium M fed from the cassette 15 and the medium M fed from the sheet feeding tray 16T. A liquid accommodating unit 98 (see FIG. 2) configured to accommodate ink serving as an example of a liquid is accommodated within the apparatus body 11. The recording unit 20 uses a liquid such as ink supplied from the liquid accommodating unit 98 to perform recording on the medium M.

The electronic apparatus 10 includes a discharging unit 19 provided between the apparatus body 11 and the image reading unit 13. The discharging unit 19 includes a discharge tray 19A that constitutes the bottom of the discharging unit 19. The discharge tray 19A is a member formed into a plate shape, and includes a mounting surface 19B on which the discharged medium M is mounted. The discharge tray 19A is sloped, at a predetermined angle, in an orientation in which the downstream of the discharge tray 19A in a discharging direction is higher than the upstream. The discharging direction is a direction in which the medium M on which printing has been performed is discharged. In addition, in the Z direction, the discharge tray 19A is disposed at a position at the +Z direction with respect to the recording unit 20.

As illustrated in FIG. 2, the electronic apparatus 10 includes a transport path T through which the medium M on which the recording unit 20 performs recording is transported. Note that FIG. 2 illustrates individual constituent components of the electronic apparatus 10 in a simplified manner. The medium M passes through the transport path T illustrated with the dashed line in FIG. 2, and is transported. The transport path T includes a main transport path T1, transport paths T2, T3, T4, and T6, and an inversion path T5. The A-B coordinate system illustrated on a Y-Z plane is an orthogonal coordinate system. The A direction is a direction intersecting the X-axis direction. The A direction is a transport direction of the medium M in a region of the transport path T that is opposed to a recording head 20H included in the recording unit 20. The direction of the A direction toward the upstream is referred to as the −A direction, and the direction toward the downstream is referred to as the +A direction.

In the present embodiment, the A direction is a direction inclined such that the +A direction is located in the +Z direction with respect to the −A direction. Specifically, the A direction is inclined in a range of 50° to 70° with respect to the horizontal direction, and more specifically, the A direction is inclined at approximately 60°. In this manner, at a recording position PH4 at which recording is performed by the recording unit 20, the transport direction of the medium M is an inclined direction that intersects both the horizontal direction and the Z-axis direction.

The main transport path T1 is merged with the transport path T6 and the transport path T2. The transport path T6 extends from an external device. The transport path T2 extends from a sheet feeding tray 16T provided at the apparatus body 11. The main transport path T1 forms a curved portion in a region that is opposed from a sensor SE4, and extends in the A direction in a region downstream of this curved portion. The transport path T3 and the transport path T4 each extending toward the discharging unit 19 is provided downstream of the transporting unit 25 in the main transport path T1. In addition, the inversion path 15 where the front and back of the medium M is inverted is also provided downstream of the transporting unit 25 in the main transport path T1. The discharging unit 19 is provided with a discharge plate (not illustrated) so as to fit the transport path T4.

Note that the inversion path T5 is a path into which, when both-side printing is performed, the medium M having a first recording surface on which printing has been performed is transported before recording is performed on a second recording surface. The medium M is inverted in this inversion path T5, and passes through the main transport path T1 again to be transported to an opposing position as in the time when recording is performed on the first recording surface. Then, recording is performed on the second recording surface.

A transport unit 24 configured to transport the medium M along the transport path T is provided at a position along the transport path T. The transport unit 24 includes a plurality of pick-up rollers 21, a plurality of transport roller pairs 22, 23, and 26, the transporting unit 25, and a plurality of flaps 27 each configured to transport the medium M accommodated in the plurality of cassettes 15. In addition, the sensor SE4 configured to detect the width of the medium M in the X direction and the transporting unit 25 described above are disposed at positions along the main transport path T1.

The transporting unit 25 is configured to support a portion of the medium M that corresponds to the opposing position that is opposed from the recording unit 20, and also transport the medium M. The flap 27 has a function of switching paths through which the medium M is transported. The pick-up rollers 21 are driven by a feeding motor (not illustrated). In addition, the transport roller pairs 22, 23, and 26 and the transporting unit 25 are driven by one or a plurality of motors (not illustrated).

The transporting unit 25 supports the medium M that is being transported. The transporting unit 25 includes two pulleys 25A, and an endless-shaped transporting belt 25B looped over the two pulleys 25A. The medium M is transported through positions that are opposed from the recording unit 20 while being drawn to a belt surface of the transporting belt 25B. As for the method of causing the medium M to be drawn to the transporting belt 25B, it is possible to employ an air suction method, or an electrostatic absorption method, or the like. In this manner, the transporting belt 25B supports the medium M while drawing it. The transporting unit 25 is disposed so as to be opposed from the recording unit 20 in the B direction.

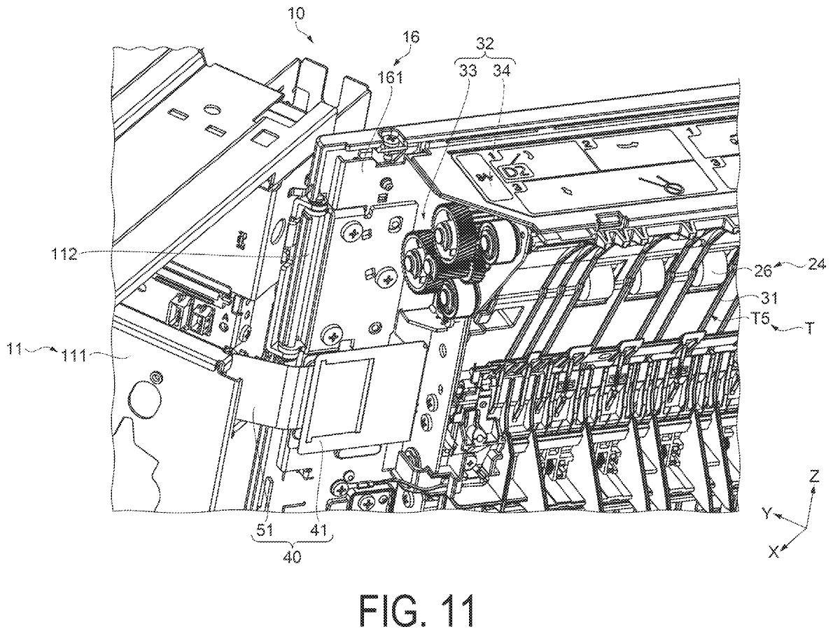

Note that a portion of the transport path T and the transport unit 24 configured to transport the medium M along a portion of the transport path T are provided at the door 16. For example, at the door 16, there are disposed a path forming member 31 that constitutes the inversion path T5, the transport roller pair 26, a driving mechanism 32 configured to drive the transport roller pair 26, various types of detectors (not illustrated), and the like, as illustrated in FIGS. 10 and 11. The driving mechanism 32 includes a toothed gear train 33 and a driving motor 34. A cover 39 covering the toothed gear train 33 is provided at a side surface, at the rotational movement shaft 112 side, of the inversion path T5 provided at the door 16. The toothed gear train 33 serves as an example of a predetermined member.

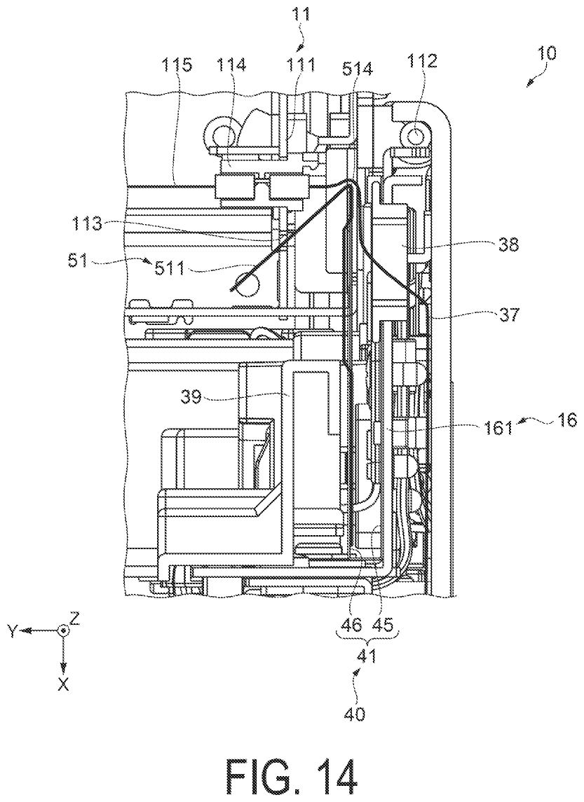

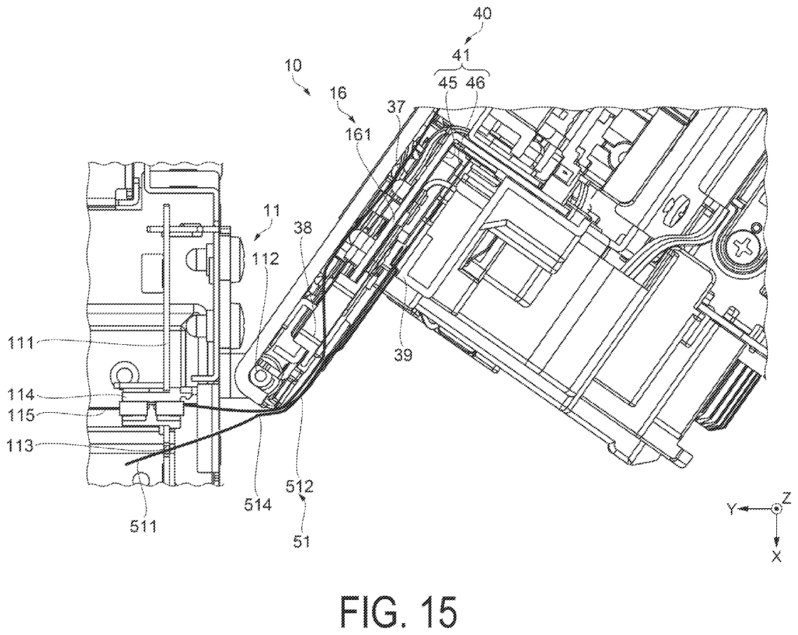

As illustrated in FIGS. 14 and 15, the driving motor 34 (see FIG. 11) and various types of detectors are electrically coupled to a printed wired board 91 (see FIG. 2) at the apparatus body 11 side through a cable 37, a relay member 114, and a cable 115. The cable 37 couples the relay member 114 provided at the apparatus body 11 to the driving motor 34 and various types of detectors provided at the door 16.

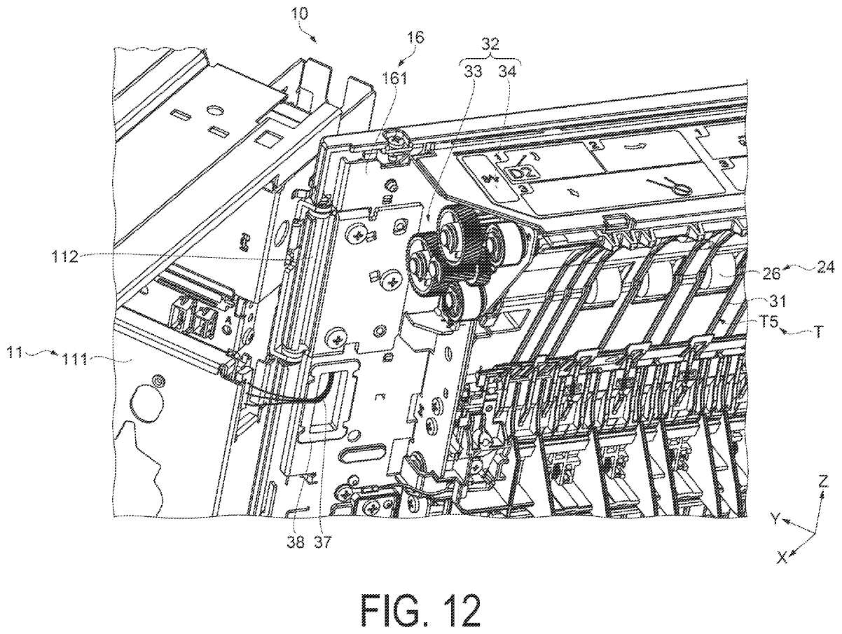

In addition, a contact preventing member 38 including a through-hole through which the cable 37 is inserted is attached at a frame 161 of the door 16, as illustrated in FIGS. 12 and 14. The contact preventing member 38 is fitted into an opening portion of the frame 161 into which the cable 37 is inserted, thereby being fixed at the frame 161. The cable 37 is inserted into the opening portion of the frame 161 into which the contact preventing member 38 is fitted. This configuration makes it possible to prevent the cable 37 from coming into contact with an end surface of the opening portion. In addition, as can be clearly understood from a comparison of FIG. 12 with FIGS. 3, 10, and 11, a cable protecting unit 40, which will be described later, is provided at a side of the cable 37 that is exposed when the door 16 is in the opened state.

As illustrated in FIG. 2, the recording unit 20 includes a recording head 20H configured to discharge ink. The recording unit 20 moves in the B direction that is a direction in which the recording unit 20 faces the transporting unit 25. In the present embodiment, the recording unit 20 reciprocates in the B direction sloped at a predetermined angle relative to the horizontal plane. The B direction is a movement direction in which the recording unit 20 advances and retreats relative to the transporting unit 25. Of the B direction, a direction in which the recording head 20H moves toward the main transport path T1 is referred to as a +B direction, and a direction in which the recording head 20H moves away from the main transport path T1 is referred to as a −B direction. The −B direction is a direction in which the recording head 20H moves toward an obliquely upward direction and along a direction in which the recording head 20H moves away from the transporting unit 25.

The B direction is a direction in which the recording unit 20 is displaced, and is a direction containing a component of the Z direction that is the height direction. In the present embodiment, the B direction is a direction sloped such that the −B direction is disposed more toward the +Z direction than the +B direction, and is perpendicular to the A direction. Furthermore, the B direction is a direction intersecting the X-axis direction.

The recording unit 20 is configured to move between a retracted position PHI illustrated in FIG. 2 with the long dashed double-short dashed line and a recording position PH4 illustrated in FIG. 2 with the solid line. By moving in the B direction, the recording unit 20 is able to move to a plurality of positions including at least the retracted position PHI and the recording position PH4. Note that the movement direction of the recording unit 20 is not limited to a direction that forms the predetermined angle relative to the horizon, and may be a horizontal direction or the Z-axis direction.

The recording unit 20 is configured such that, in a state of being disposed at the recording position PH4, the recording head 20H discharges ink or the like to a portion of the medium M that is supported by the transporting unit 25. With this configuration, the recording unit 20 performs recording of information such as an image on the medium M transported by the transport unit 24. The recording unit 20 is a line head configured such that the recording head 20H that discharges a liquid such as ink covers the entire range of the X-axis direction of the medium M that is the width direction.

The recording unit 20 performs recording in a line recording mode that makes it possible to perform recording over the entire range of the width direction of the medium M without involving movement in the X-axis direction that is the width direction of the medium M. The X-axis direction is an example of the width direction of the medium M, and is an example of the width direction of the recording unit 20. However, the recording unit 20 is not limited to this, and may be mounted at a carriage and employ a serial recording mode configured to discharge a liquid such as ink while moving in the X-axis direction.

In addition, the electronic apparatus 10 includes the printed wired board 91 within the apparatus body 11. The printed wired board 91 is provided with a control unit 95 configured to control operations of individual components of the electronic apparatus 10. The control unit 95 includes a central processing unit 96 (CPU 96), and a memory 97. The CPU 96 makes it possible to execute various types of programs held in the memory 97, and for example, is able to make various types of determination or various types of instructions or the like.

Various types of programs are held in the memory 97. The various types of programs include, for example, a program for transporting the medium M, a program for causing the recording unit 20 to perform recording on the medium M, a program concerning a display method used to display a state of the electronic apparatus 10 on the display unit 14A, and the like. In addition, the memory 97 holds various types of counter values such as the number of times that the medium M is transported to the transport path T, or the like.

The control unit 95 controls the entire electronic apparatus 10. For example, the control unit 95 controls the recording head 20H to perform discharge control to discharge a liquid such as ink from the recording head 20H. In addition, for example, the control unit 95 controls a feeding motor to cause the pick-up roller 21 to rotate, thereby feeding the medium M accommodated within the cassette 15 one by one.

Furthermore, for example, the control unit 95 controls a transport motor to drive the transport roller pairs 22, 23, and 26 and the transporting unit 25, thereby performing transport control to transport, along the transport path T, the medium M fed from the cassette 15. In addition, for example, the control unit 95 controls the image reading unit 13 to read an image on the original document D using the reading unit 13A. Furthermore, for example, the control unit 95 performs notification in which the display unit 14A of the operation unit 14 is caused to display information concerning a state of the electronic apparatus 10.

In addition, the electronic apparatus 10 includes the cable protecting unit 40 configured to protect the cable 37. As can be clearly understood from a comparison of FIG. 12 with FIGS. 3, 10, and 11, the cable protecting unit 40 is provided at a side of the cable 37 that is exposed when the door 16 is in the opened state. The cable protecting unit 40 is comprised of a base-portion member 41 and a movable member 51. The movable member 51 is provided slidably relative to the base-portion member 41.

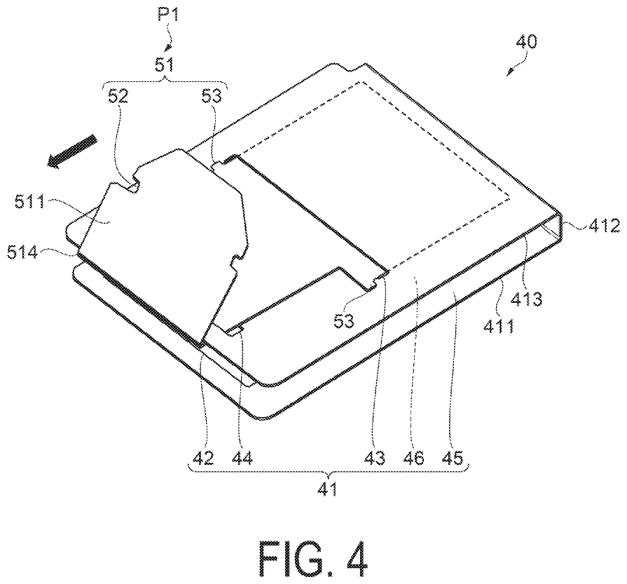

As illustrated in FIGS. 14 and 15, the base-portion member 41 is attached to the frame 161 of the door 16. The movable member 51 is locked with respect to the frame 111 of the apparatus body 11. When the door 16 is in the closed state, the movable member 51 is held, by the base-portion member 41, at an overlapping position P1 illustrated in FIG. 4.

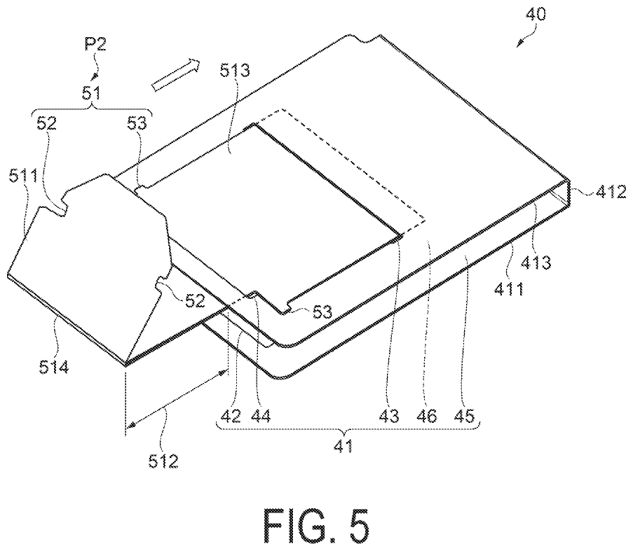

When the door 16 is displaced from the closed state (see FIG. 14) to the opened state (see FIG. 15), the movable member 51 slides from the overlapping position P1 illustrated in FIG. 4 in an extending direction indicated by a black-marking arrow, and is displaced to an extending position P2 illustrated in FIG. 5. When the door 16 is displaced from the opened state to the closed state, the movable member 51 slides from the extending position P2 in a direction indicated by a white-marking arrow illustrated in FIG. 5, and is displaced to the overlapping position P1.

As illustrated in FIG. 4 to FIG. 7, the base-portion member 41 is formed by bending a thin plate having flexibility. As for the thin plate that constitutes the base-portion member 41, it is possible to employ a thin-plate shaped resin material such as polyethylene terephthalate (PET), polypropylene (PP), polyimide (PI), a stainless steel plate, or the like.

The base-portion member 41 is bent to be separated into portions 411, 412, and 413. The portion 411 includes a first surface 45 serving as an inner side surface of the base-portion member 41. The portion 412 couples the portion 411 and the portion 413. The portion 413 is opposed from the portion 411. The portion 413 includes a second surface 46 serving as an inner side surface of the base-portion member 41 and being opposed from the first surface 45.

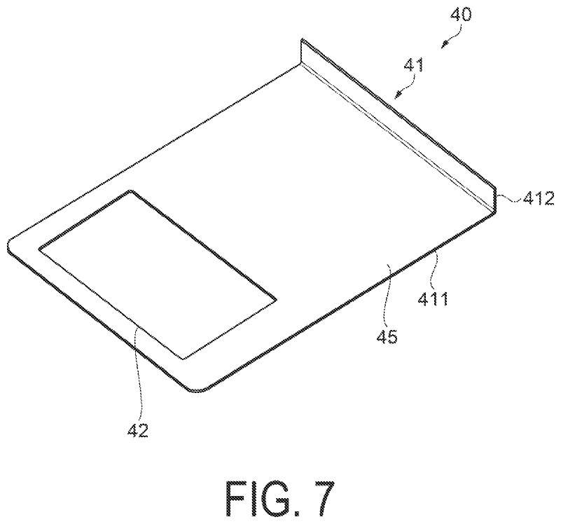

As illustrated in FIG. 7, the portion 411 includes a fastening section 42 to be fastened at the frame 161 of the door 16. The fastening section 42 is a rectangular through-hole extending through the portion 411 including the first surface 45. As illustrated in FIG. 14, the contact preventing member 38 is fitted into the frame 161 in a state in which the first surface 45 provided with the fastening section 42 is interposed between the frame 161 and the contact preventing member 38, whereby the base-portion member 41 is fixed to the frame 161. In other words, the base-portion member 41 is attached to the frame 161 with the contact preventing member 38. Note that, in FIG. 7, part of the portion 412 and the portion 413 are not illustrated for the purpose of explanation.

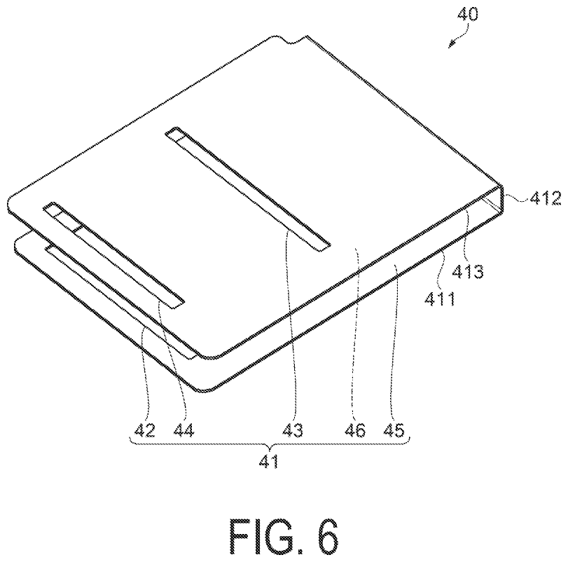

In addition, as illustrated in FIG. 6, the portion 413 includes attachment sections 43 and 44 where the movable member 51 is attached. The attachment sections 43 and 44 include a second surface 46, and are rectangular through-holes extending through the portion 413. As illustrated in FIG. 4, a tip portion 511 of the movable member 51 is inserted into the attachment section 44 from an outer side surface side of the portion 413. In addition, as illustrated in FIG. 5, an edge of a rear end portion 513 of the movable member 51 is inserted into the attachment section 43 from an outer side surface side of the portion 413.

This enables the movable member 51 to be provided slidably relative to the base-portion member 41 between the overlapping position P1 illustrated in FIG. 4 and the extending position P2 illustrated in FIG. 5. In addition, as illustrated in FIGS. 4, 5, 14, and 15, a portion of the movable member 51 that is inserted into the attachment sections 43 and 44 are located between the first surface 45 and the second surface 46. In other words, the base-portion member 41 includes the first surface 45 that is opposed from one surface of the movable member 51, and also includes the second surface 46 that is opposed from the other surface.

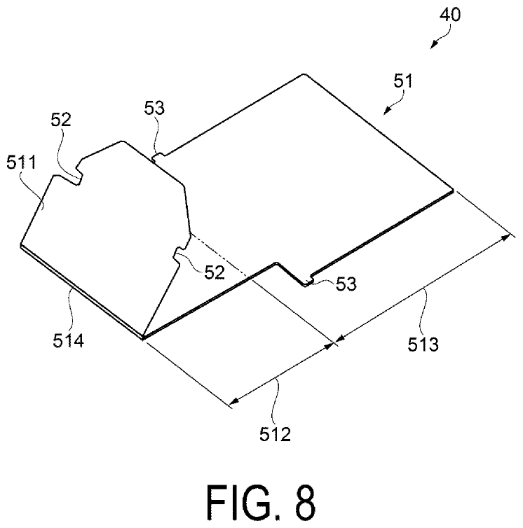

As illustrated in FIG. 8, the movable member 51 is separated into the tip portion 511, an extending section 512 continuous with the tip portion 511, and a rear end portion 513 continuous with the extending section 512. The tip portion 511 and the extending section 512 is separated by a bent portion 514.

As illustrated in FIG. 5, when the movable member 51 is located at the extending position P2, of the portion continuous with the rear end portion 513 side of the tip portion 511, the extending section 512 is a portion extending in the extending direction from the portion 413 of the base-portion member 41. Furthermore, when the movable member 51 is located at the extending position P2, of the portion continuous with the rear end portion 513 side of the tip portion 511, the ear end portion 513 is disposed within the contour of the portion 413.

In addition, as illustrated in FIG. 4, when the movable member 51 is located at the overlapping position P1, the portion continuous with the rear end portion 513 side of the tip portion 511 is disposed within the contour of the portion 413. Thus, when the movable member 51 is located between the overlapping position P1 and the extending position P2, the rear end portion 513 is disposed within the contour of the portion 413. Note that, when the movable member 51 is located at the overlapping position P1, the extending section 512 is disposed within the contour of the portion 413.

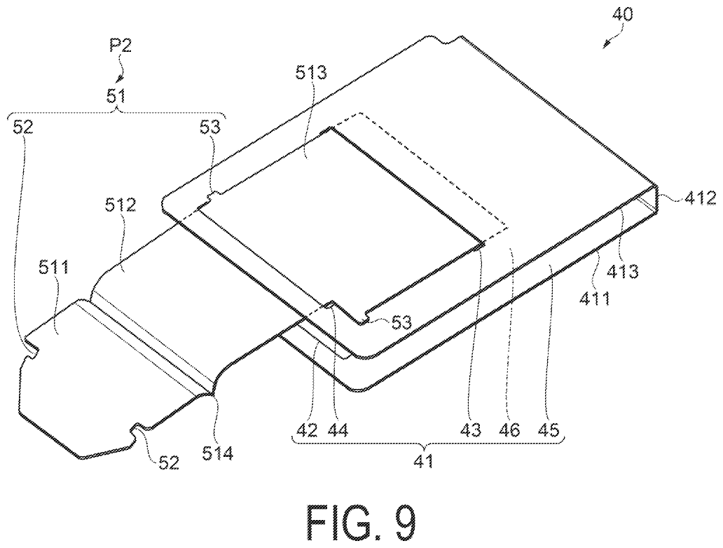

The movable member 51 is formed by bending a thin plate having flexibility at the bent portion 514. This makes it possible to cause the movable member 51 to be bent in a form in which the angle formed by the tip portion 511 and the extending section 512 is large at the bent portion 514 of the movable member 51 as illustrated in FIG. 9. As for the thin plate that constitutes the movable member 51, it is possible to employ a thin-plate shaped resin material such as polyethylene terephthalate (PET), polypropylene (PP), polyimide (PI), a stainless steel plate, or the like.

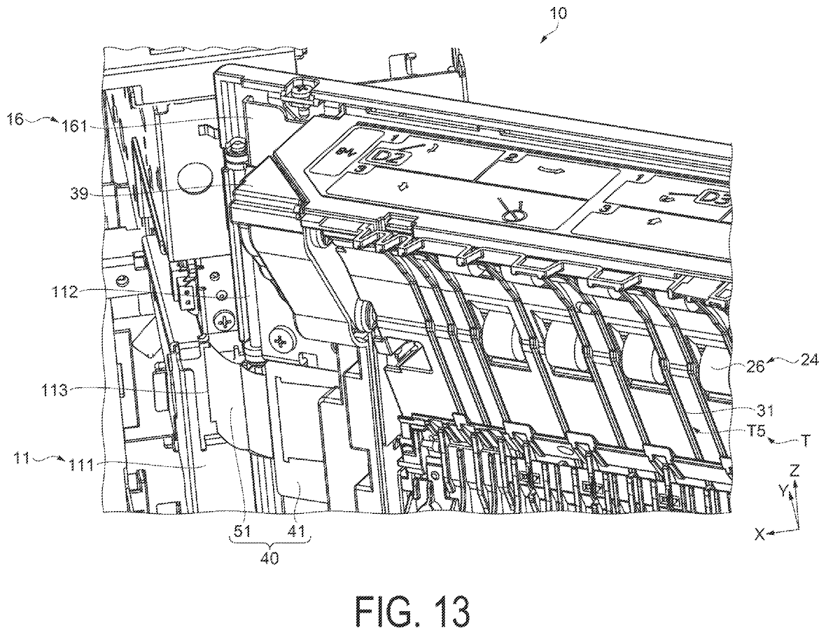

As illustrated in FIG. 8, the tip portion 511 is provided with a locking section 52 configured to be locked with respect to the frame 111 of the apparatus body 11. The locking section 52 includes an insertion section that is inserted into an engagement hole 113 (see FIGS. 13 to 15) provided at the frame 111, and also includes a locking tab provided at the tip side of the tip portion 511 and continuous with the insertion section. The locking tab has a shape that protrudes outwards further than the insertion section in the width direction of the movable member 51 that intersects the extending direction of the movable member 51. When the insertion section of the locking section 52 is inserted into the engagement hole 113 of the frame 111, the locking tab of the locking section 52 gets caught at the frame 111, and the tip portion 511 side of the movable member 51 is locked at the frame 111.

As illustrated in FIG. 8, a restriction section 53 is provided at the rear end portion 513. The restriction section 53 is provided continuous with the extending section 512 side of the sliding section of the rear end portion 513 that is to be inserted into the attachment section 43. The restriction section 53 has a shape that protrudes outwards further than the sliding section in the width direction of the movable member 51.

As illustrated in FIG. 4, the restriction section 53 comes into contact with the outer side surface of the portion 413 that defines the outline of the attachment section 43, thereby defining the length of insertion of the sliding section at the overlapping position P1. As illustrated in FIG. 5, the restriction section 53 comes into contact with the outer side surface of the portion 413 that defines the outline of the attachment section 44, thereby defining the length of extension of the extending section 512 from the base-portion member 41 at the extending position P2. In addition, the restriction section 53 comes into contact with the outer side surface of the portion 413 that defines the outline of the attachment section 44, thereby restricting detachment of the movable member 51 from the base-portion member 41.

As illustrated in FIGS. 14 and 15, when the door 16 is displaced from the closed state to the opened state, the movable member 51 slides relative to the base-portion member 41. This causes the movable member 51 to be displaced from the overlapping position P1 to the extending position P2. In addition, with the tip portion 511 and the extending section 512, the movable member 51 covers the side of the cable 37 that is exposed when the door 16 is in the opened state. Furthermore, as the extending section 512 extends from the base-portion member 41 in the extending direction, the length by which the movable member 51 extends from the base-portion member 41 increases.

In other words, when the door 16 is in the closed state, the length by which the movable member 51 extends from the base-portion member 41 is shorter than the length by which the movable member 51 extends from the base-portion member 41 when the door 16 is in the opened state. Thus, a space occupied by the cable protecting unit 40 when the door 16 is in the closed state reduces, as compared with the space occupied by the cable protecting unit 40 when the door 16 is in the opened state.

Furthermore, as illustrated in FIGS. 14 and 15, it is assumed that the cable protecting unit 40 disposed between the apparatus body 11 and the door 16 is viewed from a direction along the Z-axis. At this time, the base-portion member 41 is located between the cover 39 and the frame 161 of the door 16. In addition, at this time, the bent portion 514 of the movable member 51 is bent in a convex shape toward the rotational movement shaft 112 side. In other words, when the cable protecting unit 40 is disposed between the apparatus body 11 and the door 16, the movable member 51 includes the bent portion 514 that is bent in a convex shape toward the center of rotation of the door 16.

Note that the angle formed by the tip portion 511 and the extending section 512 at the bent portion 514 of the movable member 51 is set to be smaller than the angle by which the door 16 is opened from the closed state to the opened state with the shaft center of the rotational movement shaft 112 being the center of rotation. Furthermore, the movable member 51 has flexibility. Thus, force that causes the door 16 to be displaced to a mode of the movable member 51 illustrated in FIG. 14 when the door 16 is in the closed state acts on the movable member 51 illustrated in FIG. 15 when the door 16 is in the opened state. This enables the cable protecting unit 40 to be smoothly displaced between the mode in which the tip portion 511 is folded when the door 16 is in the closed state and the mode for protecting the cable 37 when the door 16 is in the opened state.

As described above, with the electronic apparatus 10 and the cable protecting unit 40 according to the first embodiment, it is possible to obtain the following effects.

The electronic apparatus 10 includes the apparatus body 11 and the door 16 provided displaceably to the opened state in which the door 16 is opened relative to the apparatus body 11 and the closed state in which the door 16 is closed relative to the apparatus body 11. In addition, the electronic apparatus 10 includes the cable 37 provided between the apparatus body 11 and the door 16, and also includes the cable protecting unit 40 configured to protect the cable 37. Furthermore, the cable protecting unit 40 includes the base-portion member 41, and the movable member 51 provided slidably relative to the base-portion member 41. In addition, when the door 16 is displaced from the closed state to the opened state, the movable member 51 slides relative to the base-portion member 41 to increase the length by which the movable member 51 extends from the base-portion member 41. With this configuration, the cable protecting unit 40 includes the movable member 51 configured to slide relative to the base-portion member 41. This makes it possible to suppress an increase in the size of the cable protecting unit 40 itself. Thus, the electronic apparatus 10 including the cable protecting unit 40 makes it possible to suppress an increase in the size of the electronic apparatus 10 itself.

The movable member 51 includes the locking section 52 configured to be locked with respect to the frame 111 of the apparatus body 11. This configuration makes it possible to reduce the size of the electronic apparatus 10, as compared with the configuration in which the movable member 51 is attached to the frame 111 using a fastening structure such as screw fastening.

The electronic apparatus 10 includes the frame 161 provided at the door 16 and including the opening portion into which the cable 37 is inserted, and also includes the contact preventing member 38 provided at the opening portion and configured to help prevent the cable 37 from coming into contact with the opening portion. In addition, the base-portion member 41 is attached to the frame 161 using the contact preventing member 38. With this configuration, the contact preventing member 38 is provided, which makes it possible to help prevent the cable 37 from coming into contact with the frame 161. In addition, since the base-portion member 41 is attached using the contact preventing member 38, it is possible to reduce the number of parts that constitute the electronic apparatus 10 and also reduce the space for a dedicated fastening member. Thus, it is possible to reduce the size of the electronic apparatus 10.

The door 16 includes the cover 39 covering a predetermined member. The base-portion member 41 is located between the cover 39 and the frame 161 of the door 16. With this configuration, when the base-portion member 41 is positionally shifted due to displacement, the cover 39 comes into contact with the portion 413 of the base-portion member 41, and thus it is possible to restrict displacement of the base-portion member 41. This eliminates the need of additionally providing a restriction member used to restrict the positional shift of the base-portion member 41 due to displacement. This makes it possible to reduce the number of parts that constitute the electronic apparatus 10 and also reduce the space for the restriction member. Thus, it is possible to reduce the size of the electronic apparatus 10.

The base-portion member 41 includes the first surface 45 that is opposed from one surface of the movable member 51, and also includes the second surface 46 that is opposed from the other surface. This configuration enables the movable member 51 to slide relative to the base-portion member 41.

The cable protecting unit 40 includes the fastening section 42 provided at the first surface 45 and configured to be fastened at the frame 161 of the door 16. In addition, the cable protecting unit 40 includes the attachment sections 43 and 44 provided at the second surface 46 that is opposed from the first surface 45, and the movable member 51 is to be attached at the attachment sections 43 and 44. With this configuration, the fastening section 42 and the attachment section 43, 44 are provided at surfaces differing from each other. This makes it possible to reduce the size of the cable protecting unit 40, as compared with the configuration in which the fastening section 42 and the attachment section 43, 44 are provided at one surface.

The door 16 is configured to rotate between the opened state and the closed state, and the movable member 51 includes the bent portion 514 that is bent in a convex shape toward the center of rotation of the door 16. With this configuration, it is possible to suppress noises that may be generated due to floating or irregular displacement of the movable member 51 when the door 16 is opened or closed.

The apparatus body 11 includes the transport unit 24 configured to transport the medium M along the transport path T, and the recording unit 20 configured to perform recording on the medium M transported by the transport unit 24. In addition, the door 16 can be displaced to the opened state in which the transport path T is exposed to the outside, and the closes state in which the transport path T is closed. This configuration enables the electronic apparatus 10 to achieve a recording device having the effects described above.

The cable protecting unit 40 is configured to protect the cable 37 provided between the apparatus body 11 and the door 16 configured to be displaced to the opened state in which the door is opened relative to the apparatus body 11 and the closed state in which the door is closed relative to the apparatus body 11. The cable protecting unit 40 includes the base-portion member 41 and the movable member 51 provided slidably relative to the base-portion member 41. In addition, when the door 16 is displaced from the closed state to the opened state, the movable member 51 slides relative to the base-portion member 41 to increase the length by which the movable member 51 extends from the base-portion member 41. With this configuration, as the cable protecting unit 40 includes the movable member 51 configured to slide relative to the base-portion member 41. This makes it possible to suppress an increase in the size of the cable protecting unit 40 itself.

The base-portion member 41 is attached at the door 16. In addition, the movable member 51 includes the tip portion 511 including a tip end attached to the apparatus body 11, and also includes the extending section 512 continuous with the tip portion 511. Furthermore, as the movable member 51 slides relative to the base-portion member 41, the extending section 512 moves between the overlapping position P1 at which the extending section 512 is located within the contour of the base-portion member 41 and the extending position P2 at which the extending section 512 extends from the base-portion member 41. With this configuration, as the movable member 51 overlaps with the base-portion member 41 at the overlapping position P1, the cable protecting unit 40 is able to easily achieve miniaturization of the cable protecting unit 40 itself.

The movable member 51 is a plate member having flexibility. In addition, with the tip portion 511 and the extending section 512, the movable member 51 covers the side of the cable 37 that is exposed when the door 16 is in the opened state. With this configuration, when the door 16 is in the opened state, the cable protecting unit 40 is able to protect the cable 37 in a manner such that the cable 37 is not viewed from the outside. Furthermore, when the door 16 is in the closed state, the cable protecting unit 40 is able to easily achieve miniaturization of the cable protecting unit 40 itself.

Although the electronic apparatus 10 and the cable protecting unit 40 according to the embodiments described above of the present disclosure are basically assumed to have the configurations as described above, it goes without saying that modification, omission, and the like of part of the configuration is possible within a range that does not deviate from the scope and gist of the present disclosure. Furthermore, the embodiment described above and other embodiments to be described below can be combined with each other as long as no technical contradiction arises due to the combination. Below, other embodiments will be described.

In the embodiment described above, the base-portion member 41 may not be attached at the frame 161 of the door 16. In addition, the movable member 51 may not be locked with respect to the frame 111 of the apparatus body 11. For example, the base-portion member 41 may be attached at the frame 111 of the apparatus body 11. In this case, the tip portion 511 of the movable member 51 may be attached at the frame 161 of the door 16. Alternatively, in this case, the tip portion 511 of the movable member 51 may be attached at the cover 39.

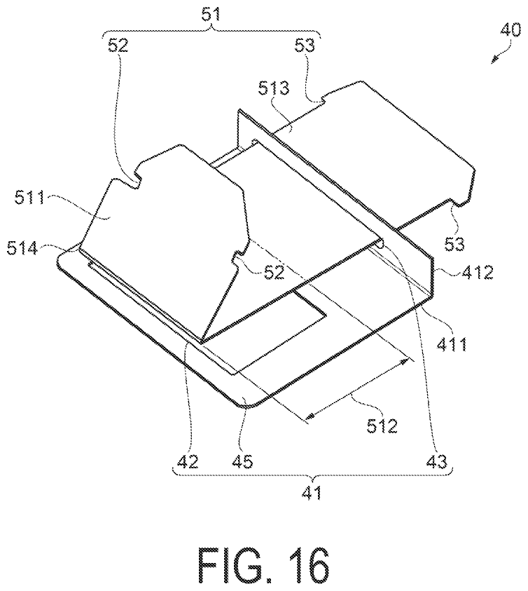

In the embodiment described above, the base-portion member 41 may not include the portion 413 including the second surface 46. In this case, as illustrated in FIG. 16, the base-portion member 41 may include the attachment section 43 at the portion 412. In addition, in this case, the movable member 51 may include the restriction section 53 at an end of the rear end portion 513 that serves as a rear end of the movable member 51. In addition, the rear end portion 513 of the movable member 51 is inserted into the attachment section 43 from the inner side surface side of the portion 412. This makes it possible to attach the movable member 51 slidably relative to the base-portion member 41. In addition, the restriction section 53 comes into contact with the outer side surface of the portion 412 that defines the outline of the attachment section 43, thereby defining the length of extension of the extending section 512 from the base-portion member 41. Furthermore, the restriction section 53 comes into contact with the outer side surface of the portion 412 that defines the outline of the attachment section 43, thereby restricting detachment of the movable member 51 from the base-portion member 41.

In the embodiment described above, the base-portion member 41 may not have flexibility. For example, the base-portion member 41 may be formed through injection molding of a resin material. In addition, for example, the base-portion member 41 may be made through casting of a metal material such as iron or aluminum alloy. In these cases, the base-portion member 41 may have a box shape. The side of this box shape in the extending direction in which the movable member 51 extends is opened.

In the embodiment described above, the movable member 51 may be configured such that the movable member 51 is able to expand and contract in an extending direction. In this case, the movable member 51 may include, at the tip portion 511, an accordion shape having a structure in which a mountain fold and a valley fold are repeated.

In the embodiment described above, the driving motor 34 and various types of detectors disposed at the door 16 may not be electrically coupled to the printed wired board 91 at the apparatus body 11 through the cable 37, the relay member 114, and the cable 115. For example, the driving motor 34 and various types of detectors may be electrically coupled directly to the printed wired board 91 at the apparatus body 11 side through the cable 37. In this case, the relay member 114 or the cable 115 may not be provided.

In the embodiment described above, the door 16 may include a relay substrate to which the driving motor 34 and various types of detectors are electrically coupled. In this case, the driving motor 34 and various types of detectors are electrically coupled to the printed wired board 91 at the apparatus body 11 side through the cable 37, the relay member 114, and the cable 115 electrically coupled to the relay substrate.

In the embodiment described above, a detector may not be disposed at the door 16. In this case, the driving motor 34 is electrically coupled to the printed wired board 91 at the apparatus body 11 side through the cable 37, the relay member 114, and the cable 115.

What is claimed is:

1. An electronic apparatus comprising:
an apparatus body;
an opening-closing member provided displaceably to an opened state in which the opening-closing member is opened relative to the apparatus body and a closed state in which the opening-closing member is closed relative to the apparatus body;
a cable provided between the apparatus body and the opening-closing member; and
a cable protecting unit configured to protect the cable, wherein
the cable protecting unit includes
a base-portion member and
a movable member provided slidably relative to the base-portion member and
when the opening-closing member is displaced from the closed state to the opened state, the movable member slides relative to the base-portion member to increase a length by which the movable member extends from the base-portion member.

2. The electronic apparatus according to claim 1, wherein
the movable member includes a locking section configured to be locked with respect to a frame of the apparatus body.

3. The electronic apparatus according to claim 1, further comprising:
a frame provided at the opening-closing member and including an opening portion into which the cable is inserted; and
a contact preventing member provided at the opening portion and configured to help prevent the cable from coming into contact with the opening portion, wherein
the base-portion member is attached to the frame with the contact preventing member.

4. The electronic apparatus according to claim 1, wherein
the opening-closing member includes a cover covering a predetermined member and
the base-portion member is located between the cover and a frame of the opening-closing member.

5. The electronic apparatus according to claim 1, wherein
the base-portion member includes:
a first surface facing one surface of the movable member and
a second surface facing another surface of the movable member.

6. The electronic apparatus according to claim 5, wherein
the cable protecting unit includes:
a fastening section provided at the first surface and configured to be fastened at a frame of the opening-closing member and
an attachment section that is provided at the second surface facing the first surface and at which the movable member is attached.

7. The electronic apparatus according to claim 1, wherein
the opening-closing member is configured to rotate between the opened state and the closed state and
the movable member includes a bent portion bent in a convex shape toward a center of rotation of the opening-closing member.

8. The electronic apparatus according to claim 1, wherein
the apparatus body includes:
a transport unit configured to transport a medium along a transport path and
a recording unit configured to perform recording on the medium transported by the transport unit and
the opening-closing member is configured to be displaced to the opened state in which the transport path is exposed to an outside and the closed state in which the transport path is closed.

9. A cable protecting unit configured to protect a cable provided between an apparatus body and an opening-closing member configured to be displaced to an opened state in which the opening-closing member is opened relative to the apparatus body and a closed state in which the opening-closing member is closed relative to the apparatus body, the cable protecting unit comprising:
a base-portion member; and
a movable member provided slidably relative to the base-portion member, wherein
when the opening-closing member is displaced from the closed state to the opened state, the movable member slides relative to the base-portion member to increase a length by which the movable member extends from the base-portion member.

10. The cable protecting unit according to claim 9, wherein
the base-portion member is attached to the opening-closing member,
the movable member includes a tip portion including a tip end attached to the apparatus body, and an extending section continuous with the tip portion, and
the movable member slides relative to the base-portion member to cause the extending section to move between an overlapping position at which the extending section is located within a contour of the base-portion member and an extending position at which the extending section extends from the base-portion member.

11. The cable protecting unit according to claim 10, wherein
the movable member is a plate member having flexibility, and covers, with the tip portion and the extending section, a side of the cable exposed when the opening-closing member is in the opened state.
